(19) United States
(12) Patent Application Publication
(10) Pub. No.: US 2007/0009652 A1
(43) Pub. Date: Jan. 11, 2007

(54) Continuous OLED coating machine

(76) Inventors: Dieter Manz, Schlaitdorf (DE); Marcus Bender, Hanau (DE); Uwe Hoffmann, Alzenau (DE); Dieter Haas, Bruchkobel (DE); Ulrich Englert, Heigenbrucken (DE); Heino Lehr, Rodenbach (DE); Achim Gurke, Aschaffenburg (DE)

Correspondence Address: LOWRIE, LANDO & ANASTASI, RIVERFRONT OFFICE, ONE MAIN STREET, ELEVENTH FLOOR, CAMBRIDGE, MA, 02142, US

(21) Appl. No.: 11/406,806

(22) Filed: Apr. 19, 2006

(30) Foreign Application Priority Data
Apr. 20, 2005 (EP) 05008669.3
Apr. 6, 2006 (EP) 06112340.2

(51) Int. Cl. B05D 5/12; C23C 16/00; C23C 14/00

(52) U.S. Cl. 427/58; 118/50; 118/715; 118/66; 430/311; 118/721

(57) ABSTRACT

Aspects of the present invention concern a device and a process for continuous production of substrates provided with organic electroluminescent materials (OLED), especially OLED displays, screens, panels or other lighting elements, in which the device has a vacuum space and a transport device for transporting the substrates to be coated, which is at least partially arranged along the vacuum space and comprises carriers for the substrates, with the transport device comprising at least one endless loop for transport of the carriers and with the vacuum space being divided at least into two with a first part, in which is provided a first section of the transport device for transporting the carriers in a first direction (substrate-transport direction), and with a second part, in which is provided a second section of the transport device for transport of the carriers in a second direction (carrier-return-transport direction). Correspondingly, the masks necessary for structuring the OLED coatings are cleaned advantageously directly during return transport and no mask stockpiling is required.

### RELATED APPLICATION

This application relates to U.S. patent application Ser. No. ______ entitled PROCESS AND DEVICE FOR POSITIONING THE MASK (Attorney Docket No. A2022-700010), by Dieter Manz, filed on even date herewith, and U.S. patent application Ser. No. ______ entitled MAGNETIC MASK HOLDER (Attorney Docket No. A2022-700110), by Dieter Manz, filed on even date herewith. Both of these related applications are incorporated herein by reference.

### FIELD OF THE INVENTION

Aspects of the present invention relate to a device and a process for the production of substrates provided with organic electroluminescent materials (OLED).

### RELATED ART

In the field of technical actuating elements and entertainment electronics, flat panels and displays are gaining increasingly in importance. An interesting realization of such flat panels is afforded by so-called OLED displays or screens in which organic electroluminescent materials between electrodes are deposited on a flat, transparent substrate in order that, by means of actuation via the electrodes, light emissions which can be used for producing an image may be generated.

Vacuum-coating processes, generally in so-called cluster tools, are used for the production of such OLED screens. There are usually arranged about a center various modules in which different coating steps are performed, with a centrally arranged robot inserting the substrates to be coated into the corresponding modules, removing them again and transporting them to the next module. While such a technology offers certain advantages with regard to purity requirements and process conditions in the individual modules, it is not meaningful for economic mass production of corresponding OLED screens.

For this reason, there are already proposals in the prior art for so-called in-line machines, which facilitate a continuous sequence of the various necessary coating steps. Examples here are JP 2003332052 A, WO 03/090260 A 2 and WO 03/043067 A 1.

JP 2003332052 A proposes an annular arrangement of different coating stations, for example for the deposition of red-, green- and blue-emitting electroluminescent materials, with a separate cleaning station for the masks necessary for structuring the coatings proposed outside the ring at an outfeed station. However, such a machine configuration requires a high outlay for the separate transport path of the cleaned masks to the infeed station as well as regards the separate arrangement of the cleaning stations.

WO 03/090260 A 2 A describes a device for depositing multi-layer coatings on substrates, with the substrates guided several times through the coating machine on an essentially linear track in order that the different layers may be deposited. Although a continuous in-line machine is realised thereby, such a machine has disadvantages due to the repeated travelling of the substrate through the coating machine.

WO 03/043067 A 1 describes a device for the production of organic electroluminescent, light-emitting devices for mass production in which the substrate to be coated is arranged on carrier, which, for example, is guided along a track arrangement through a vacuum-coating machine and in which the carriers with the substrate can dip into adjacent coating chambers in order that a wide variety of coating processes may be performed.

Here, too, the outlay for lowering the substrates into the individual coating chambers is very high, both temporally during the coating process and from the design aspect.

Additionally, all processes, such as substrate cleaning, mask arrangement for structuring, and cleaning of the masks as well as the coatings in the various chambers are performed in succession.

### SUMMARY OF THE INVENTION

At least one aspect of the invention is directed to create a coating machine or a device for especially continuous production of a substrate provided with organic electroluminescent materials (OLED), especially OLED displays, screens, panels or other OLED lighting elements, in which the disadvantages of the prior art are avoided and especially a simple and favourable possibility for mass production of OLED elements is provided, combined with a small space requirement and with allowance for high quality standards for the OLED products. In at least one version the corresponding device is easy to manufacture and the process easy to operate.

One aspect of the invention is characterised by the fact that the coating machine or device is constructed on the dual-chamber principle, i.e. that the entire vacuum space of the vacuum-coating machine is preferably divided into two parts along its longitudinal axis, with a first part of the vacuum space used to transport the carriers loaded with the substrates to be coated through the coating machine from the loading to the unloading station and the other, second part of the machine serving to return and clean the substrate carriers and especially the masks required for structuring. This has the advantage that a very compact machine with genuine continuous operation can be realized as a so-called in-line machine, in which stockpiling of both carriers and masks is largely avoided by guiding carriers and/or masks in endless loops, and the throughput and efficiency are substantially increased.

Furthermore, by virtue of the dual-chamber principle, simple construction and simple operation, especially also for the generation of the vacuum, are possible, with especially the dual chambers capable of being formed as all-round modules, such that corresponding process tools and other devices can be arranged in the corresponding dual-chamber modules, as required. This greatly facilitates conversion as well. Moreover, such a construction facilitates uninterrupted transport of substrates or carriers and/or masks for microstructuring the coatings in the vacuum. As a result, contamination of the carriers or masks by the environment is avoided.

Further, where necessary, lock chambers and/or lock devices and isolating devices can be provided between the individual chambers or chamber modules in order that specific areas may be sealed off to avoid contamination or in the event of partial venting of the machine.

Aside from the endless loop for transporting the carriers, which, with the first section of the transport device, extends along the first part of the vacuum space in the direction of substrate transport and, with the oppositely directed, second section of the transport device, i.e. in the carrier-return-transport direction, extends in the second part of the vacuum room or the vacuum dual chambers, preferably several second endless loops for transporting masks are advantageously and additionally preferably provided which serve the purpose of structuring or microstructuring the coatings. The corresponding transport arrangements of the second endless loops for transporting the masks have a first section also in that part of the vacuum space in which substrate transport from the infeed area to the outfeed area takes place, and have a second section for the return transport in the second part of the vacuum space.

In addition, preferably at least one transport branch may be provided in which the transport device for the substrate carrier and/or the transport arrangement for the masks is not formed as a continuous loop, but instead parallel transport sections in the same and/or opposite direction are provided in the dual chambers. This can be advantageous in the infeed and outfeed areas especially, since, in this way, both parts of the vacuum dual chambers can be used for transporting the substrates on the substrate carriers to and away from the mask-placement station, and as a result the efficiency can be greatly enhanced. Correspondingly, more substrates can be diverted in quick succession into the coating process, a fact which further increases the efficiency of the machine.

Preferably, the transport devices for the carriers and the transport arrangements for the masks use partly the same transport means and handling devices, such that at least some transport occurs jointly. Especially, the substrate carriers serve preferably also as mask carriers for the at least partial return transport of the masks.

Preferably, the changeover from the first section of the transport device or the transport arrangement to the second section of the transport device or transport arrangements occurs in the endless loops and vice versa in the substrate-loading stations and/or substrate-unloading stations in which the substrates are arranged at the carriers or are removed from these and/or in the mask-placement stations and/or mask-removal stations at which the masks are assigned to the substrates or are arranged on or removed again from these.

In a preferred embodiment, a rotation module is provided which, in one station, performs not only mask exchange for two adjacent coating areas but also effects transfer of the masks from the coating section to the cleaning section and vice versa, with corresponding mask-placement and/or removal stations and/or mask-alignment stations and holding elements for the masks being provided at the rotation module.

The rotation module comprises a rotary mechanism with a rotary table on which are provided two pick-ups with transfer positions for substrate carriers from both the first section and the second section of the transport device, whereby, through rotation of the rotary table through 180 degrees, the pick-ups can be moved into the transfer positions of the respective other transport section and, on rotation through 90 degrees, into transfer positions for transfer to an adjacently arranged mask and/or substrate-carrier exchange area. First, the masks are removed in the mask-exchange areas from the substrate carriers, then the substrate carriers are assigned to the respective other waiting mask and, after placement, moved further along the transport system.

Preferably, masks and/or substrate-carrier magazines can be provided along the transport route for the substrate carriers and/or masks in order that substrate carriers and/or masks may be exchanged or in order that, given the different duration of handling processes, optimisation of throughput and the efficiency of the device may be effected. Further, the magazines can also be used to load the machine. Preferably, such intermediate magazines, which may have one or especially several storage places, are assigned to the transfer devices, the mask-placement and/or mask-removal stations and/or the rotation modules. Through use of substrate-carrier or mask-transfer units, which offer corresponding rotary and/or translatory movements for the respective handling possibilities, the corresponding substrate carriers and/or masks can be simply diverted into and out of the transport process again and moreover exchanged between magazine units, for example several magazines arranged together.

Like the mask- and/or substrate-carrier magazines, additional mask- and/or substrate-carrier cleaning stations can also be provided in side-branches outside the actual transport route, such that, through brief outfeed from the actual transport route, cleaning of the masks and/or the substrate carriers can be effected. This can take place especially in addition to cleaning, which can occur during return transport in the second section or in the second part of the vacuum chamber.

The endless loops can each be realised by a single continuously operating transport device or by a plurality of handling devices and transport means, in which, for example, the substrates and/or carriers or the masks are transferred from one device to the other. Correspondingly, transport of masks and/or substrate carriers can take place completely continuously, i.e. without stopping, or discontinuously with intermediate stopping and/or any combination thereof. Occasional return transport into individual stations is thus possible and conceivable as well. Thus, coating or general treatment of the substrates can also take place dynamically, i.e. during transport, or statically, in which the substrate is not moved. Consequently, there are three basic possibilities for types of coating or treatment that can be combined with each other, namely continuous dynamic, timed dynamic or static.

In at least one embodiment of a device, it is possible, given corresponding processes for production of OLED elements, during return transport to directly clean the masks or shadow masks required for structuring of the coatings and to avoid or reduce mask stockpiling as well as to minimise the number of necessary masks overall.

### BRIEF DESCRIPTION OF DRAWINGS

Further advantages, characteristics and features of the present invention are apparent from the following details description of two embodiments using the enclosed drawings. The drawings show in purely schematic form:

FIG. 1 shows a plan view of a device in-accordance with one embodiment of the invention;

FIG. 1A shows a partial diagram of a transfer device used in at least one embodiment;

FIG. 2 shows a plan view of a second embodiment of a device in accordance with the invention;

FIG. 3 shows a partial view of the device from FIG. 2 with corresponding carriers and masks;

FIG. 4 shows a schematic diagram of a part of the process sequence or operation of the device from FIGS. 2 and 3;

FIG. 5 shows a plan view of a rotation module in a further embodiment of the invention;

FIG. 6 shows a plan view of a third embodiment of the device of the invention in the form for production of white OLEDs; and in

FIG. 7 shows a plan view of a fourth embodiment of a device in accordance with the invention in the form of an RGB-OLED coating.

### DETAILED DESCRIPTION

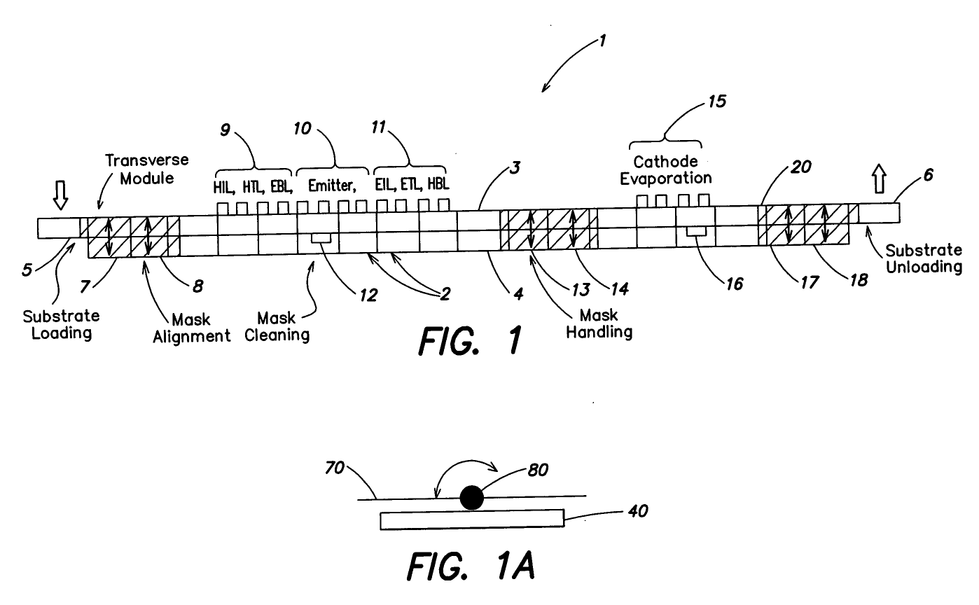

FIG. 1 shows a device in accordance with one embodiment of the invention configured for generating organic LEDs (OLED) that emit white light. Device 1 comprises a plurality of vacuum dual chambers 2 in succession, each of which is split into parts (halves) 3 and 4 and which form a vacuum space with their neighbouring chambers. Aside from the division of the vacuum space into the two parts 3 and 4 along the longitudinal axis of the device, the vacuum space is additionally subdivided in the embodiment shown in FIG. 1 by mask-placement station 14 and mask-removal stations 13 into two areas, with a subdivision into several areas also possible. However, like the longitudinal subdivision into parts 3 and 4, the subdivision by the mask-placement and removal stations 13 and 14 is not to be understood as indicating that different vacuum conditions obtain. Although this is possible in individual cases, equal vacuum conditions can instead also prevail. The subdivision is only to be understood as meaning that the vacuum space is not continuously the same. However, the vacuum dual chambers 2, each with their parts 3 and 4, form continuous transport areas, which moreover are not interrupted by the mask-placement and removal stations 13 and 14, while a transition between parts 3 and 4 is possible only in certain areas. Nor does the subdivision of the vacuum space by the modules of the vacuum dual chambers 2 influence the basic subdivision into parts 3 and 4.

Additionally, a separation can be effected by providing locks or isolating elements 20, which facilitate separation or isolation of individual areas of the vacuum space. Preferably, the vacuum space is constructed of similar modules, which, in line with their use as mask-placement and removal stations or substrate-loading and unloading stations, coating stations and the like, are equipped in different ways.

Device 1 has an overall linear construction, with a substrate-infeed device 5 provided at one end and a substrate-outfeed device 6 at the opposite end. Apart from the linear construction, it is naturally possible to have a different construction with corresponding curves or transport around a corner. By means of the substrate-infeed device 5 and the substrate-outfeed device 6, the substrate to be coated can be diverted into or out of the vacuum space of device 1 from ambient conditions or a different vacuum-treatment machine.

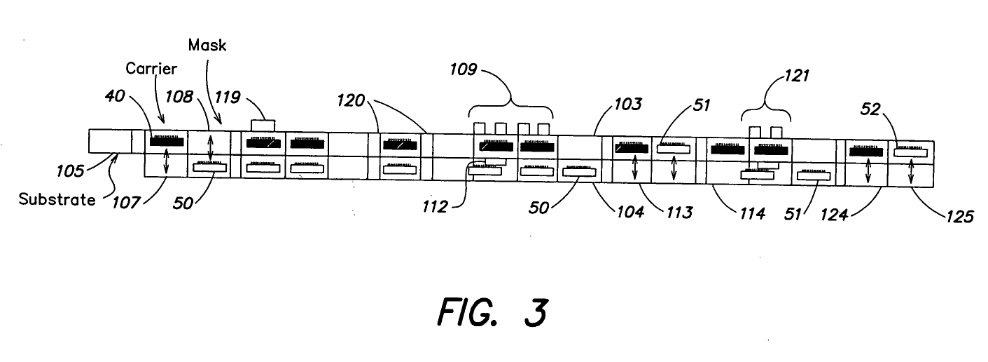

The substrate-infeed device 5 is followed, after a lock or isolating device by a substrate-loading station 7, in which the substrate to be coated is arranged on a carrier 40 (see FIG. 3), on which the substrate is located during the coating process or during transport through device 1. At the same time, substrate-loading station 7 makes available a transfer device, as shown in the partial diagram of FIG. 1A, which facilitates an exchange of carrier 40 from part 4 of the vacuum space into part 3 of the vacuum space and vice versa. As will be shown later, carrier 40 in the substrate-loading station changes its direction of transport from the carrier-return-transport direction to the substrate-transport direction.

Alternatively, the substrate-loading station can also be provided in the substrate-infeed device, such that handling of the substrate during positioning on the substrate carrier can take place simply in air and not in the vacuum. In that event, the substrate-infeed device would be followed only by a transfer module, in which the returned substrate carrier from part 4 is transferred into part 3 and subsequently transported into the substrate-infeed device for loading. The outfeed area could also be arranged correspondingly.

After the substrate-loading station 7 comes mask-placement station 8, in which a mask (shadow mask) (see FIG. 3) is placed on or assigned to the substrate arranged on or at carrier 40 in order that, during subsequent coating, structuring of the coating may be obtained in such a manner that the substrate is not coated in the areas covered by the mask, while coating does occur in the other areas. Additionally, the mask is aligned or adjusted here in order that structuring may occur in exactly the right position.

The mask-placement station 8 also comprises a transfer device with the aid of which a mask from part 4 of the vacuum space can be transferred to part 3 of the vacuum space, with the mask simultaneously also changing transport direction from the return transport direction into a substrate-transport direction. Given a corresponding configuration with handling and holding devices substrate-loading station 7 and the mask-placement station 8 can also be combined in a single station.

Mask-placement station 8 is followed by a plurality of vacuum dual chambers 2, which are fitted out for the corresponding coating processes in or at part 3.

In the embodiment shown in FIG. 1, coating areas 9, 10 and 11 are provided, in which corresponding auxiliary layers are applied, such as hole injection layer HIL, hole transport layer HTL and electron blocking layer EBL in area 9, light-emitting material in area 10 and further auxiliary layers, such as electron injection layer EIL, electron transport layer ETL and hole blocking layer HBL in area 11.

After the carrier with the substrate thereon and the mask have travelled through coating areas 9 to 11, it passes into the connecting mask-removal station 13, where the mask is removed from the substrate. Mask-removal station 13, too, has a transfer device, by means of which the removed mask is transferred to part 4 of the vacuum space where it is transported back to the mask-placement station 8 in the opposite direction to substrate transport, which, in the embodiment of FIG. 1 proceeds from left to right. In one of the vacuum dual chambers 2 en route, there is a mask-cleaning station 12 which, as the mask is being transported back, cleans the mask directly and removes the coating materials applied in coating stations 9 to 11. In this way, the mask can be re-used immediately in mask-placement station 8. Cleaning can be performed in any suitable way.

Meanwhile, the carrier with the substrate moves into the mask-placement station 14, which is arranged after the mask-removal station 13, and in which, as in mask-placement station 8, a new mask is in turn applied to the substrate in order that an appropriately adjusted mask may be provided for subsequent electrode application by thermal evaporation.

In mask-placement station 14, just as in mask-placement station 8, the corresponding mask is transferred from part 4 of the vacuum space to part 3 of the vacuum space, with the mask changing its direction of transport. Moreover, just as in mask-placement station 8, the mask is aligned in mask-placement station 14, such that structuring of the coating material to be applied occurs precisely in those areas in which the structures are necessary.

The vacuum dual chambers 2 in area 15 after mask-placement station 14 are equipped such that the electrode material can be thermally evaporated onto the substrate. Naturally, other evaporation processes are also usable.

After travelling through coating station 15, the substrate on the carrier and the mask arranged thereon pass into mask-removal station 17, where the mask is in turn removed from the substrate and transferred to part 4 of the vacuum space, such that the mask can be transported back, in the opposite direction to substrate transport, and cleaned in cleaning station 16 so that it is immediately available again in the mask-placement station.

In the following substrate-loading station 18 for the carrier, the substrate is removed from the carrier and transported to the substrate-outfeed station 6, while the carrier is transported to part 4 of the vacuum space and moved back to the substrate-loading station 7.

During return transport of the carrier in the preferred embodiment shown, mask and carrier are transported jointly, with, in this case, the carrier in mask-removal station 17 picking up the mask for the return transport and correspondingly transferring it again in mask-placement station 14. In the same manner, during return transport in part 4 of the vacuum space in mask-removal station 13, the carrier picks up the mask from the previous coating process and transports it to mask-pick-up station 8. However, provision of separate means of transport for carriers and masks is also conceivable for the return transport.

Overall, in the embodiment of FIG. 1, the result is three endless loops, more precisely a first endless loop for the carrier of the substrate, which moves from substrate-loading station 7 in part 3 of the vacuum space (upper row in the diagram) via mask-placement station 8 and coating stations 9 to 11, mask-removal station 13 as well as mask-pick-up station 14 and coating station 15 as far as substrate-unloading station 18 where it changes its direction of transport and then is transported in turn as far as substrate-loading station 7 in the direction opposite to substrate transport. In addition to this first endless loop, there are two second endless loops as regards mask transport, more precisely one for the mask for the coating processes in coating stations 9 to 11 and the other for the mask for the coating processes in coating station 15. The mask for the coating process in coating stations 9 to 11 moves from the mask-placement station 8 via coating stations 9 to 11 as far as mask-removal station 13, where the mask changes its direction of transport and is transported via mask-cleaning station 12 in part 4 of the vacuum space back to mask-placement station 8.

The other mask of the coating process of coating station 15 moves from mask-placement station 14 in part 3 of the vacuum space via coating station 15 to mask-removal station 17, where it also changes direction of transport and is transported via cleaning station 16 in part 4 back to mask-placement station 14.

These endless loops, expressed in terms of the objects moved, that is the endless loops from the viewpoint of the carrier or the masks, can be formed by a plurality of handling and transfer devices. However it is also conceivable that a single continuous conveying device is provided especially for the movement of the carrier.

In the same manner, diverse manifold devices for picking up and moving the masks, carriers, substrates etc. are conceivable for substrate-loading and unloading stations 7 and 18 as well as mask-placement and removal stations 8 and 14 on one hand and 13 and 17 on the other.

A conceivable transfer device, for example, for substrate-loading and unloading stations 7 and 18 as well as mask-placement and removal stations 8, 13, 14 and 17, is a simple rotary mechanism in which carrier plate 70 rotates or pivots about an axis 80, more precisely through 180 degrees, such that carrier 70 points once with its corresponding side towards part 3 of the vacuum space and, after rotation through 180 degrees, the next time towards part 4 of the vacuum space. Given a vertical alignment of the substrate, that is an alignment perpendicular to the plane of the diagram of FIG. 1 and corresponding vertical transport, rotary axis 80 of pivotable carrier plate 70 is thus also arranged perpendicular to the plane of the diagram. A corresponding illustration is shown in FIG. 1A with carrier plate 70 having a central axis 80 about which carrier plate 70 can pivot as shown by the double-headed arrow, such that substrate carrier 40 can be rotated between parts 3 and 4 of the vacuum space.

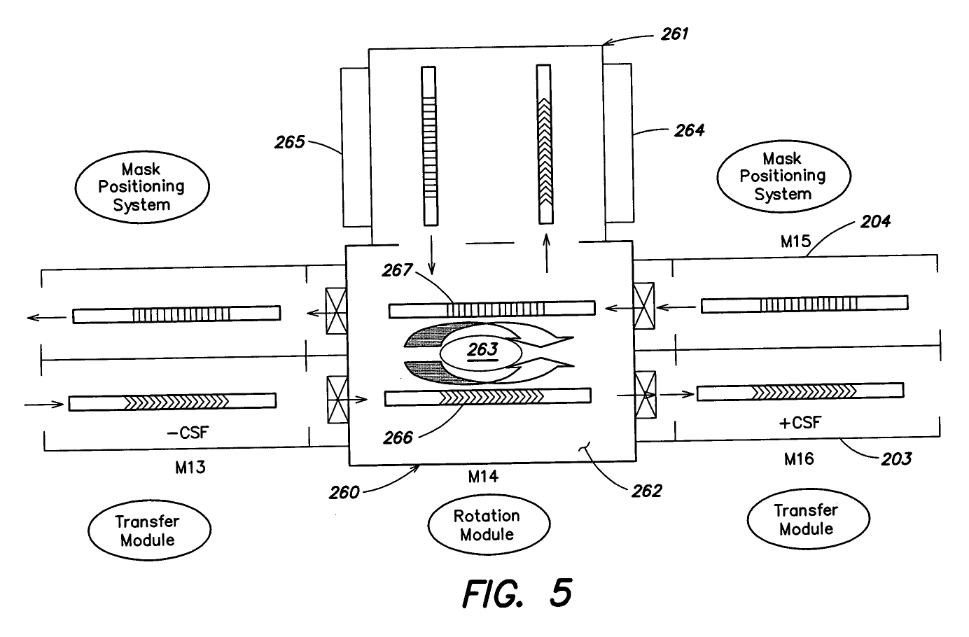

In this way, it is also particularly simple to realise a combination of substrate-loading and unloading stations 7, 18 and mask-placement and removal stations 8, 13, 14, 17, 18, for example of mask-removal station 13 and mask-placement station 14, since only corresponding intermediate holding devices need to be provided for the parts to be received and placed. A corresponding rotation module is described below in connection with FIG. 5.

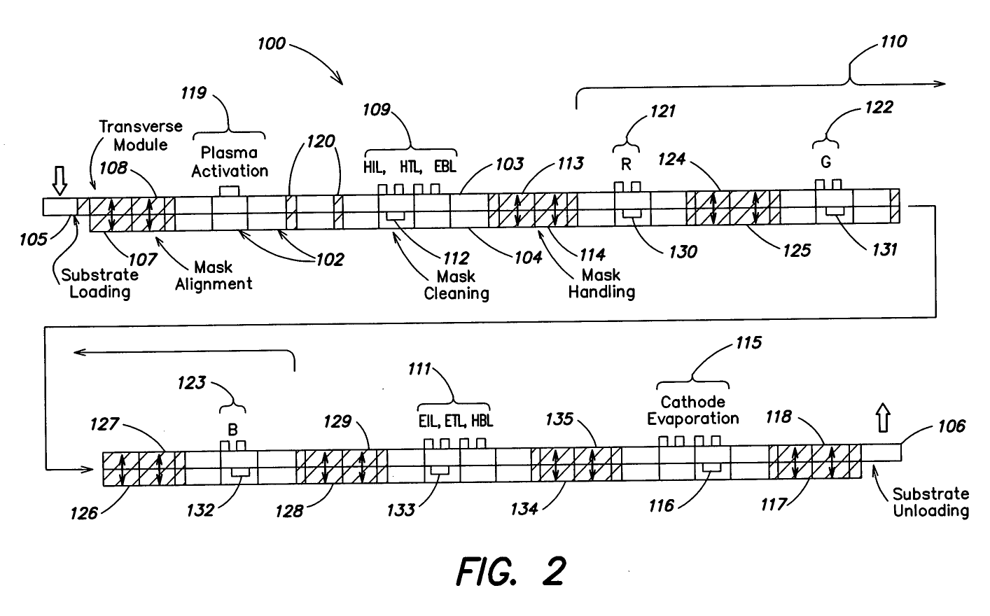

FIG. 2 shows a further embodiment of a device in accordance with the invention for the production of so-called RGB displays, in which pixels of red-, blue- and green-emitting electroluminescent materials have to be produced separately from each other in a structured fashion. Correspondingly, different maskings, with corresponding mask-placement and removal stations 124, 125, 126, 127, 128, 129, have to be provided for the red-, green-and blue-emitting electroluminescent materials to be deposited. Correspondingly, cleaning station 130 is assigned also to coating station 121 for the red-emitting electroluminescent materials, cleaning station 131 to green coating station 122, and cleaning station 132 to blue coating station for the corresponding masks.

Coating stations 121, 122 and 123 together form coating area 110 for the electroluminescent material. Additionally, coating areas 109 and 111, corresponding to coating areas 9 and 11 of the embodiment in FIG. 1 are also provided in which the corresponding auxiliary layers, such as hole inducing layer, hole transport layer, EBL layer, electron inducing layer, electron transport layer and HBL layer are applied. To these coating stations 109 and 111, too, are assigned cleaning stations 112 and 133 for the masks used there. Moreover, aside from electrode-coating station 115, plasma-activation station 119 is provided at the start of device 100 in which the substrate or its surface is plasma-activated for the subsequent coating.

Device 100, too, along with its vacuum space is divided into two along its longitudinal axis, into part 103 and part 104, with, in part 103 or correspondingly at parts 103 of vacuum dual chambers 102 provided there, the corresponding substrate-treatment and coating stations 109, 110, 111, 115 and 119 provided, while cleaning stations 112, 130, 131, 132, 133 and 116 are assigned to or are arranged at or in part(s) 104.

Like the lock or isolating device 20 of the embodiment in FIG. 1 for separating or isolating individual areas, especially in the area of the mask-placement and removal stations, in the embodiment of device 100 are provided corresponding lock or isolating devices 120, which, for example, are provided between plasma-activation station 119 and coating station 109 for separating the corresponding atmospheres and forming a lock area for the substrates.

The overall result is that device 100 has a-construction with a substrate-infeed station 105, a substrate-loading station 107, a mask-placement station 108 and an endless loop for the carrier with transport means, which moves the carrier with applied substrate and changing masks first past plasma-activation station 119, then past coating station 109 and then past further coating stations 121, 122, 123,and 111 as well as 115 to finally separate the substrate from the carrier in the substrate-unloading station 118 and to issue the substrate in substrate-outfeed station 106 or make it available to subsequent treatment devices. The carrier, without substrate and again with changing masks, is then moved back in the second part 104 of the vacuum space to the substrate-loading station 107, passing cleaning stations 116, 133, 132, 131, 130 and 112 in that order.

Apart from this first endless loop, device 106 has two endless loops for the corresponding masks, with the first mask in mask-placement station 108 being arranged and aligned on the substrate or the carrier relative to the substrate in order that the substrate may be protected and only exposed in the corresponding areas of previously defined areas as it is passing through plasma-activation station 119 and coating station 109. This mask is removed in mask-removal station 113 from the substrate or the carrier and transported back through mask-cleaning station 112 to mask-placement station 108 in vacuum partial space 104. If plasma activation of the entire surface of the substrate is desired, mask-placement and alignment station 108 can also be provided between plasma-activation station 119 and coating station 109. Instead of plasma activation, other processing techniques for cleaning and/or activation of the surface, especially surface-activation techniques, are conceivable, such as UV, ozone treatment or ion bombardment.

The second endless loop of the second kind for transporting a corresponding mask is provided for coating area 121, with the mask placed and adjusted in mask-placement station 114, removed from the substrate or carrier in mask-removal station 124 and cleaned in cleaning station 130.

The third, fourth, fifth and sixth endless loops of the second kind are assigned to coating stations 122, 123, 111 and 115, with, in each of the corresponding mask-placement stations 125, 127, 129 and 135, the masks for the subsequent coating process placed and aligned on the substrate or carrier, while the corresponding masks are removed again in mask-removal stations 126, 128, 134 and 117 after the respective coating stations.

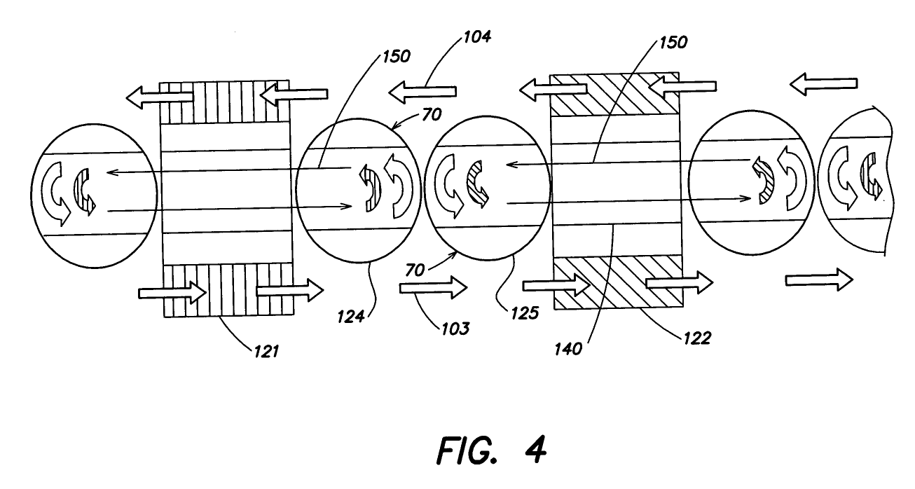

This mode of operation is illustrated more clearly by the schematic diagrams of FIGS. 3 and 4, with FIG. 3 showing the transport or movement flow for carrier 40 and masks 50 and 51 or 52 for a partial section of device 100 from FIG. 2. As may be clearly seen in FIG. 3, several carriers and masks always move simultaneously not only in the first but also in the second endless loop, such that high throughput through the coating machine is guaranteed. As indicated by the double-headed arrows in mask-placement stations 108, 114 and 125 and mask-removal stations 113 and 124 as well as substrate-loading station 107, carrier 40 is exchanged in these stations from the second section of the transport device for the carrier in part 104 of the vacuum space to the first section of the transport device in part 103 of the vacuum space, and for the masks from the second section of the transport arrangement for the masks in part 104 of the vacuum space to the first section of the transport arrangement of the masks in part 103 of the vacuum space (mask-placement stations) and vice versa (mask-removal stations).

As is especially evident from FIG. 4, the schematically shown first endless loop 140 and second endless loop 150 preferably have identical transport means and handling devices for realising the transport device for the carrier and the transport arrangement for the masks.

FIG. 4 is a schematic visualisation of mask transfer during exchange from red coating station 121 to green coating station 122 in mask-removal station 124 and mask-pick-up station 125 and by, for example, rotatable carrier plates 70, as shown in FIG. 1. In mask-removal station 124, the carrier with the mask from red coating area 121 is transferred by rotation of carrier plate 70 from the first part 103 of the vacuum space to the second part 104 of the vacuum space, where it transfers the mask for the red coating area. Then, carrier plate 70 is rotated back such that carrier 40 on carrier plate 70 with the substrate arranged thereon is again located in the area of first part 103 of the vacuum space. There follows further transport of the substrate with the carrier into mask-placement station 125 of green area 122, where, in turn, carrier plate 70 is first rotated through 180 degrees, such that the substrate with the carrier is in turn arranged in part 104 of the vacuum space. There, the carrier or the substrate takes the mask from the green area, returned and cleaned in part 104 of the vacuum space, and, after arrangement and alignment of the green mask, is rotated back by means of a rotation through 180 degrees into part 103 of the vacuum space, such that, there, transport of the carrier with substrate and now green mask through the green area can be continued. This type of sequence is realisable between all coating and substrate-treatment stations and also for the substrate-loading and unloading stations.

Given use of corresponding handling means permitting short-term intermediate storage of at least one of the corresponding masks, a combination of mask-placement and mask-removal stations in a single station is conceivable, as shown in FIG. 5. However, for the avoidance of mutual contamination of the various coating areas, spatial separation is advantageous, even if this entails somewhat greater handling outlay. However, such a combination can be realized for coating stations or substrate-treatment stations in which no contamination need be feared or if corresponding means-of separation are provided.

In the example of FIG. 5, a rotation module 260 with a rotation area 262 and a mask-exchange area 261 is provided. Into rotation module 260 in part 203 of the transport device in which coating takes place are introduced substrate carriers 266 with correspondingly coated masks, while, in part 204, substrate carriers 267 with cleaned masks from the adjacent coating area are transferred, with the transport directions being opposed. After pick-up of substrate carriers 266, 267 on rotary table 263, the latter is rotated through 90 degrees such that substrate carriers 266, 267 can be transferred by linear motion to adjacent mask-exchange area 261. There, arranged on the outer walls, mask-positioning systems 264 and 265 take the masks from substrate carriers 266, 267. While mask-positioning systems 264 and 265 hold the masks, the substrate carriers are moved again to rotary table 263, rotated there through 180 degrees and again introduced into mask-exchange area 261. There, substrate carrier 266 takes the cleaning mask from the following coating area, while substrate carrier 267 with the coated mask, after a further rotation through 90 degrees, moves into the cleaning area of the other coating area.

A mask-cleaning station can be attached at the side of rotary area 262 opposite mask-exchange area 261, for example, when the rotation module in the infeed area is used.

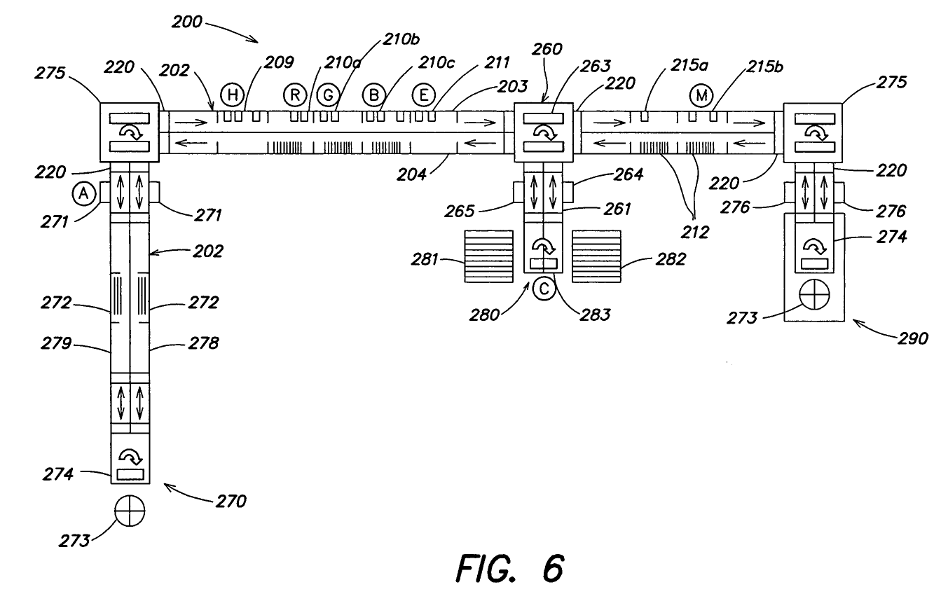

FIG. 6 shows a schematic representation of a further device in accordance with the invention for the production of diodes that emit white, organic light (white OLED). Device 200 shown in FIG. 6 again has a plurality of vacuum dual chambers 202 arranged in succession that are separated from each other only at a few points by a rotation module 260 and two turning modules 275 and several isolating devices 220.

Except for rotation module 260, which replaces the mask-placement and removal stations of FIG. 1, the device corresponds in its coating areas to the device from FIG. 1, such that the same end digits have been chosen in the list of terms for identical or comparable components.

In addition, device 200 from FIG. 6 differs from device 1 of FIG. 1 in that different substrate infeed and outfeed devices 270, 290 are provided.

Substrate-infeed device 270 has a robot 273, which transfers the substrates to the substrate carriers in a transfer module 274. The transfer module is designed such that the substrate carriers in it can be rotated about an axis perpendicular to the image plane and can execute linear movements, such that the substrate carrier can be taken from transport sections 278 and 279 of vacuum dual chambers 202 and transferred to these.

A special feature of substrate-infeed device 270 consists in the fact that both transport sections 278 and 279 in vacuum dual chamber 202 can serve to feed substrates to the two mask-placement stations 271. This means that, in parallel transport sections 278 and 279, both unidirectional and counter-directional transport are possible, in contrast to the anti-parallel transport in the coating areas.

In addition, not only is feeding of substrates to mask-placement stations 271 possible in transport sections 278 and 279 of substrate-feeding device 270, but also transport of the substrate carriers in the direction of transfer module 274. Correspondingly, substrate-cleaning stations 272 are also provided, which serve to clean the substrate carriers.

This type of arrangement of substrate feed effects a marked increase in efficiency and throughput, since more substrates can thus be sent on their way through the coating areas. Especially, substrate-infeed device 270 with turning module 275 can work at a very much higher cycle frequency than the transport device in the area of the coating areas.

Further, in the area of rotation module 260, two substrate-carrier magazines 281 and 282 are provided which are connected to each other by a substrate-carrier-transfer module 283 and to rotation module 260. This storage unit 280 thus facilitates intermediate buffering of the substrate carriers to facilitate optimisation of the throughput of substrates through the coating machine. Moreover, there is the possibility of exchanging defective substrate carriers. Additionally, the storage unit can serve to load the machine with substrate carriers. As for the rest, rotation module 260 functions as described with reference to FIG. 5.

Like the substrate-infeed area, substrate-outfeed area 290 has a turning module 275, mask-removal stations and/or intermediate storage 276 and a substrate-carrier-handling or transfer module 274 that interacts with a robot 273. Substrate-transfer module 274 and robot 273 are arranged in a so-called glove box with inert atmosphere.

In the case of substrate-outfeed device 290, too, the two transport sections of vacuum dual chambers 202, at which corresponding mask-removal or storage units 276 are arranged, are traversable in both directions for the substrate carriers, such that here, too, rapid outfeed of the substrates is possible.

Especially, the transport speed in the individual areas and sections can be different in order that optimum use of the entire device may be facilitated. Thus, for example, the speed in the transport branches of substrate-infeed device 270 and substrate-outfeed device 290 can be different from transport speeds in coating areas 209 to 211 and 215a and 215b. Additionally, the transport speeds can also differ in the coating areas, and also in the sections, i.e. in part 203 of the vacuum dual chamber and the other part 204 of the vacuum dual chamber. Thus, the transport speed in the coating part can be different from the transport speed in the area of return transport. This facilitates optimised utilisation of the entire device.

In detail, device 200 of FIG. 6 functions in such a way that the substrates are transferred via robot 273 to the substrate carriers, which are made available in substrate-transfer unit 274. From there, the substrate carriers loaded with the substrates are transported via a lock to transport sections 278 or 279 of substrate-infeed device 270 in the direction of mask-placement stations 271. There, the masks returned from part 204 via cleaning stations 212 are placed on the substrate. The substrate provided with the mask is introduced with the substrate carrier into part 203 of the vacuum chamber arrangements via turning module 275, more precisely for example by means of a corresponding rotation of substrate-carrier pick-ups. At the same time, a returned substrate carrier with a cleaned mask from part 204 can be transferred to substrate-infeed device 270, with the mask being removed in mask-placement station 271 and stored temporarily until the substrate carrier with the substrate returns from substrate-transfer module 274.

Thus, in the embodiment shown, the substrate introduced into part 203 of the vacuum chambers travels through coating areas 209, 210a, 210b, 210c and 211, where, for example, a hole injection layer, a hole transport layer, a red emitter layer, a green emitter layer, a blue emitter layer, a hole blocking layer and an electron injection layer are applied in that order. Then, the substrate with the mask arranged thereon is picked up in rotation module 260, where the mask is removed in mask-removal station 265, and is then transported back again in part 204 of the vacuum chamber, while the coating substrate in mask-placement station 264 takes a new mask, which is required for the subsequent coating process in coating chambers 215a and 215b.

Connected to mask-exchange area 261 of rotation module 260 is a substrate-carrier-transfer module 283, which serves two substrate-carrier magazines 281 and 282. Substrate carriers can be exchanged here accordingly.

Subsequently, the substrate with the new mask, still in part 203 of the vacuum chamber, is guided further through coating stations 215a and 215b, where LiF evaporation and then aluminium evaporation and corresponding deposition take place. Thereafter, the substrates on the substrate carriers with the masks are transferred to a turning module 275 of the substrate-outfeed device 290, from where they pass into mask-removal station 276 and the substrate carrier is unloaded in substrate-transfer unit 274, 273. This takes place in inert gas atmosphere in a so-called glove box.

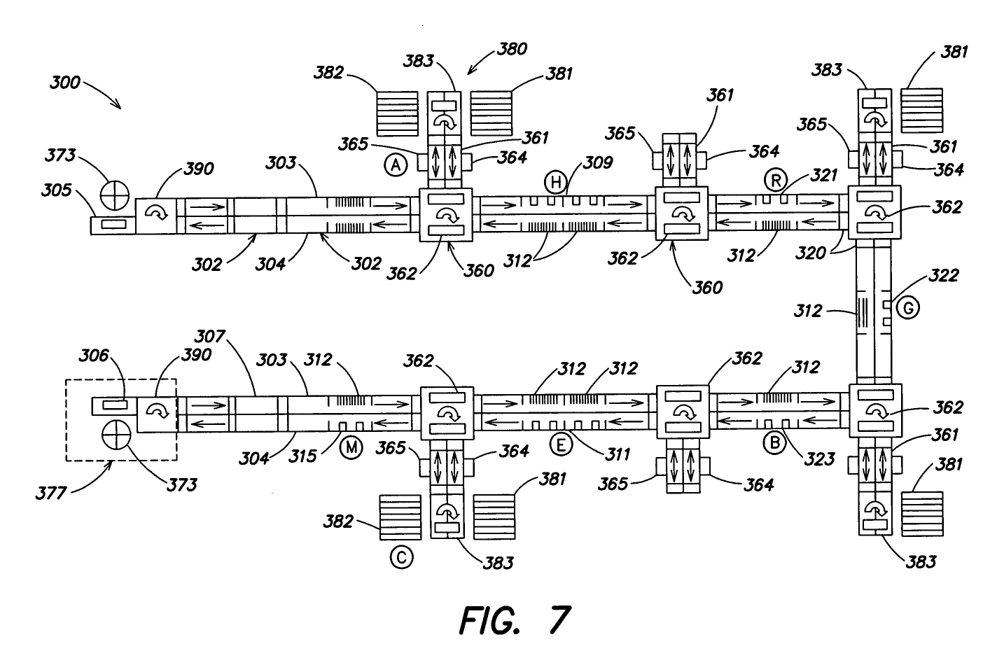

FIG. 7 shows a fourth embodiment 300 in which, again, similar or identical components have the same end digits as in the previous embodiments. Device 300 is a coating machine for the production of so-called RGB-OLED systems in which, therefore, differently-coloured LEDs are deposited alongside each other. This machine therefore essentially corresponds to the machine concept of embodiment 100, with the difference being that mask-placement and removal stations 113 and 114 as well as 124, 125, 126, 127, 128, 129, along with 130, 134 and 135 have been replaced by corresponding rotation modules 360. These, in turn have a rotary area 362, a mask-exchange area 361 with mask-placement station 264 and mask-removal and intermediate storage station 365. Like the embodiment of FIG. 6, substrate-carrier-transfer units 383 with one or two substrate-carrier magazines 381, 382 are provided at mask-exchange areas 361 in several rotation modules 360.

Substrate infeed with substrate-infeed device 305, following transfer by robot 373 as well as substrate outfeed with substrate-outfeed device 306 and transfer to robot 373 proceed similarly as in the embodiment of FIG. 2. However, only turning modules 390 and transfer modules are provided here, which facilitate only transfer of the substrate carrier from part 304 to part 303 of the vacuum chambers. Substrate placement occurs in substrate-infeed device 305, while substrate removal occurs in substrate-outfeed device 306.

### LIST OF TERMS

| | |
|---|---|
| 1, 100, 200, 300 | Coating machines |
| 2, 102, 202, 302 | Vacuum dual chamber |
| 3, 4; 103, 104; 203, 204; 303, 304 | Parts of the vacuum dual chambers |
| 5, 105, 305 | Substrate-infeed device |
| 6, 106, 306 | Substrate-outfeed device |
| 7, 107 | Substrate-loading station |
| 8, 14, 108, 114, 125, 127, 129, 138, 271 | Mask-placement station |
| 9, 109, 209, 309 | Coating area for hole injection layers, hole |
| | transport layers, electron blocking layers |
| 10, 109, 110, 111, 121, 122 123, 210, | Coating areas for light-emitting materials |
| 321, 322, 323 | |
| 11, 111, 211, 311 | Coating areas for hole blocking layers, electron |
| | injection layers, electron transport layers |
| 12, 16, 112, 116, 130, 131, 132, 133, | Cleaning stations for masks |
| 212, 312 | |
| 13, 17, 113, 117, 124, 126, 128, 134 | Mask-removal station |
| 15, 215a, 215b | Coating area for electrode |
| 18 | Substrate-unloading station |
| 20, 120, 220 | Lock and isolating device |
| 40, 266, 267 | Substrate carrier |
| 50, 51, 52 | Masks |
| 70 | Carrier plate |
| 80 | Axis |
| 119 | Plasma activation |
| 140 | First endless loop |
| 150 | Second endless loop |
| 260, 360 | Rotation module |
| 261, 361 | Mask-exchange area |
| 262, 362 | Rotation area |
| 263 | Rotary table |
| 264, 265; 364, 365 | Mask-exchange system |
| 270 | Substrate-infeed device |
| 271 | Substrate-cleaning station |
| 272, 273 | Robots |
| 274 | Transfer module |
| 275 | Turning module |
| 278, 279 | Transport steps |
| 280 | Storage unit |
| 281, 282; 381, 382 | Substrate-carrier magazines |
| 283, 383 | Substrate-carrier-transfer module |
| 290 | Substrate-outfeed device |
| 390 | Turning module |

Having thus described several aspects of at least one embodiment of this invention, it is to be appreciated various alterations, modifications, and improvements, will readily occur to those skilled in the art. Such alterations, modifications, and improvements are intended to be within the spirit and scope of the invention. Accordingly, the foregoing description and drawings are by way of example only.

What is claimed is:

1. A system for use in the production of substrates to be provided with organic electroluminescent materials (OLED), the system comprising:
at least one vacuum chamber defining a vacuum space having a first part and a second part; and
a transport device for transporting the substrates to be coated at least partially through the vacuum space, the transport device including carriers for the substrates, and at least one endless loop for transporting the carriers, a first section of the transport device being configured to transport the carriers in a first direction, and a second section of the transport device being configured to transport the carriers in a second direction.

2. The system in accordance with claim 1, wherein the at least one vacuum chamber includes a plurality of vacuum chambers arranged beside each other and permit uninterrupted transport of at least one of the substrates the carriers and masks in the vacuum space.

3. The system in accordance with claim 2, wherein at least some of the plurality of vacuum chambers have dual chambers that define the first part and the second part of the vacuum space.

4. The system in accordance with claim 1, wherein the system includes at least one lock chamber along the endless loop.

5. The system in accordance with claim 1, further comprising at least one second, endless loop for transporting masks in the vacuum space, the at least one second endless loop having a first section and a second section, with the first section being provided in the first part of the vacuum space and the second section being provided in the second part of the vacuum space.

6. The system in accordance with claim 1, further comprising:
at least one substrate-loading station for loading of substrates onto carriers;
at least one substrate unloading station for unloading of substrates from the carriers; and
at least one mask station for performing at least one of mask placement, mask removal and mask alignment.

7. The system in accordance with claim 1, further comprising at least one transfer device to transfer at least one of carriers and masks from the first part of the vacuum space to the second part of the vacuum space.

8. The system in accordance with claim 1, further comprising
at least one coating station provided along the first endless loop, wherein the at least one coating station is configured to perform at least one of chemical vapour phase deposition (CVD), physical vapour phase deposition (PVD), sputtering processes, plasma-aided coating processes, and evaporation processes with or without carrier gas;
at least one, cleaning station provided along the first endless loop, the at least one cleaning station configured for cleaning at least one of the substrates, the carriers and masks; and
at least one substrate treatment station provided along the first endless loop, wherein the at least one substrate treatment station is configured to perform at least one of substrate activation, plasma activation, UV treatment, ozone treatment, ion bombardment, and spark discharge treatment.

9. The system in accordance with claim 1, further comprising
at least one second endless loop for transporting a mask.

10. The system in accordance with claim 1, further comprising
a plurality of second endless loops for transporting masks.

11. The system in accordance with claim 8, wherein the at least one coating station and the at least one substrate treatment station are arranged along the first section of the transport device in the first part of the vacuum space, and the at least one cleaning station is arranged along one of the first section and second section of the transport device in one of the first part and the second part of the vacuum space.

12. The system in accordance with claim 1, further comprising:
a rotation module having a rotary area, a mask-exchange area, and a rotary mechanism provided in the rotary area, said rotary mechanism capable of switching between the transport device sections and/or the mask-exchange area.

13. The system in accordance with claim 1, further comprising at least one magazine for use with one of masks and substrate-carriers.

14. The system in accordance with claim 12, wherein the mask-exchange area has a first mask-exchange position and a second mask exchange position, wherein the first mask-exchange position is arranged to provide mask alignment for placement of a mask on a substrate to be coated, and wherein the second mask-exchange position is arranged to provide return transport of a mask on a carrier.

15. The system in accordance with claim 12, further comprising a substrate-carrier magazine with at least one substrate-carrier exchange unit provided for taking and transferring substrate carriers to and from at least one of the substrate-carrier magazine and adjacent machine components.

16. The system in accordance with any claim 12, further comprising one or more cleaning stations for cleaning at least one of masks and substrates, the one or more cleaning stations being configured to receive at least one of masks and substrates from the rotation module.

17. The system in accordance with claim 1, wherein the transport device includes at least one transport branch having two parallel sections each having a substantially same transport direction.

18. The system in accordance with claim 17, wherein the at least one transport branch is positioned adjacent one of a substrate-loading device and a substrate-unloading device.

19. The system in accordance with claim 1, wherein, the at least one endless loop includes at least one of a single continuous conveying device and a plurality of handling and transfer devices.

20. The system in accordance with claim 1, wherein the at least one endless loop includes a first endless loop and a second endless loop having at least one common conveying and handling device.

21. The system in accordance with claim 1, wherein the first section of the at least one endless loop has an inlet and an outlet, and wherein the system includes a substrate-infeed device adjacent the inlet and a substrate-outfeed device adjacent the outlet.

22. The system of claim 1, wherein the system is formed as a continuously operating, essentially linear (in-line) machine.

23. A process for producing substrates provided with organic electroluminescent materials (OLED), the process comprising:
a) arranging a substrate on a carrier for transport in a first direction through a vacuum-coating machine in a substrate-loading station;
b) placing a mask on one of the substrate and the carrier in a mask-placement station,
c) coating the substrate;
d) removing the mask in a mask-removal station and transporting the mask in a second direction to the mask-placement station, wherein the first direction is substantially opposite the second direction;
e) cleaning the mask during transport in the second direction;
f) providing a cleaned mask in the mask-placement station; and
g) transporting the carrier with the coated substrate for unloading from the vacuum-coating machine or execution of further coating.

24. The process of claim 23, wherein transporting the mask in a second direction includes transporting the mask in a vacuum.

25. The process in accordance with claim 23, wherein stages b, c, d, e, f and g are repeated a plurality of times in succession.

26. The process in accordance with claim 23, further comprising unloading the substrate, and transporting the carrier in the second direction towards the substrate-loading station.

27. The process in accordance with claim 23, wherein the mask and the carrier are transported together for at least part of a transport path.

28. The process in accordance with claim 23, further comprising transferring a direction of travel of the mask from one of the first direction and the second direction to the other of the first direction and the second direction in at least one of the mask-placement station and the mask-removal station.

29. The process in accordance with claim 23, wherein the first direction and the second direction are along a transport path, and wherein the method further comprises storing at least one of carriers and masks in magazines positioned along the transport path.

30. The process in accordance with claim 23, wherein cleaning of the mask during transport occurs either during transport or using cleaning stations with brief interruption of transport.

31. The process in accordance with claim 23, wherein a speed of travel of carriers in the first direction is different from a speed of travel of carriers in the second direction.
